(19) United States
(12) Patent Application Publication
(10) Pub. No.: US 2026/0095047 A1
(43) Pub. Date: Apr. 2, 2026

(54) GRID-FORMING PLANT CONTROLS FOR SELF-SUPPLY AND BLACK START APPLICATIONS OF DC ENERGY STORAGE SYSTEMS

(71) Applicant: Fluence Energy, LLC, Arlington, VA (US)

(72) Inventors: Ioannis Arvanitis, Berlin (DE); Stefan Henninger, Obermichelbach (DE)

(73) Assignee: Fluence Energy, LLC, Arlington, VA (US)

(21) Appl. No.: 19/345,534

(22) Filed: Sep. 30, 2025

Related U.S. Application Data
(60) Provisional application No. 63/701,506, filed on Sep. 30, 2024.

(51) Int. Cl. H02J 3/00; G01R 31/382; H02J 3/32; H02J 3/38; H02J 3/40

(52) U.S. Cl. CPC H02J 3/001; G01R 31/382; H02J 3/32; H02J 3/381; H02J 3/40

(57) ABSTRACT

A power plant includes a plant controller in communication with and operatively connected to a plurality of BESSs. Each of the plurality of BESSs is composed of a plurality of BESS enclosures, a bus bar including a bus coupler, and a plurality of BESS circuit breakers. Each of the plurality of BESSs is connectable via a respective one of the plurality of BESS circuit breakers to the bus bar to supply electric power to an electric grid. The plant controller is arranged to control the bus coupler to separate the plurality of BESSs into a first network and a second network, control the first network to operate the power plant in a self-supply mode when the bus coupler is in an open state, and control the second network to operate the power plant in black-start mode when the bus coupler is in the open state.

### CROSS REFERENCE TO RELATED APPLICATION

This application claims the benefit of, and right of priority to, U.S. Provisional Patent Application No. 63/701,506, filed Sep. 30, 2024, and entitled “GRID-FORMING PLANT CONTROLS FOR SELF-SUPPLY AND BLACK START APPLICATIONS OF DC ENERGY STORAGE SYSTEMS,” the contents of which are expressly incorporated by reference as if fully set herein.

### INTRODUCTION

The concepts described herein relate generally to direct current (DC) energy storage systems, and more specifically, to modular DC energy storage systems that supply power to an electric grid.

A modular DC energy storage system includes multiple energy storage system modules that are selectively interconnected to provide varied levels of storage capacity for electrical energy generated from one or more sources, and supply electrical energy to public and/or private consumer(s) via electric grid(s). The modular DC energy storage system may be used to store additional power produced by an external power source during periods of reduced demand, and provide additional power to external power sources during periods of increased demand.

Each modular DC energy storage system includes an array of multiple energy storage system modules that are connected via one or multiple bus bars. Each energy storage system module includes one or multiple rechargeable energy storage system enclosures, a power converter, a transformer, a core circuit breaker, and a controller.

A battery energy storage system (BESS) is one form of a modular DC electric energy storage system having multiple battery energy storage system modules that are interconnected.

A black-start mode is a process of restoring, after a power outage or shutdown, an electric power station to operation without relying upon an external power source.

### SUMMARY

The concepts described herein relate to a plant controller for battery energy storage systems (BESS) that provides self-supply and black start capability. Unlike conventional project specific black start solutions, the disclosed control architecture introduces a standardized interface between a remote terminal unit (RTU) and a generic BESS (system) controller, enabling seamless integration of site-specific breaker configurations, busbar topologies, and operational data into a common software framework. The plant controller supports multiple operational modes including self-supply, black start, and hybrid operation, with automated state-of-charge (SoC) balancing through core-swapping algorithms to ensure extended auxiliary power supply during outages. The approach allows scalable, and reliable deployment of BESS black start applications across different grid configurations (single busbar, bus coupler, and double busbar), validated through controller-hardware-in-the-loop testing.

The concepts described herein further provide a battery energy storage system (BESS) including a plant controller and associated method that is capable of operating in a self-supply mode and a black-start mode, and an auxiliary power circuit. The BESS is sized to be able to supply electrical power to an electric grid, e.g., a public grid, a local industrial grid, a personal grid, etc., when connected via a main circuit breaker. Among other benefits, the present teachings address a need for a BESS having an auxiliary power circuit that provides black-start capability and self-start of electric power.

An aspect of the disclosure may include the plant controller being in communication with and operatively connected via a subsystem controller to a power plant that includes a battery energy storage system (BESS). The BESS is composed of a plurality of BESS modules, one or multiple bus bars, one or multiple bus couplers, and a plurality of core circuit breakers. Each of the plurality of BESS modules is connectable via a respective one of the plurality of core circuit breakers to the bus bar to supply electric power to the electric grid.

Another aspect of the disclosure may include a bus bar coupler. The plant controller is arranged to control the bus coupler to separate the plurality of energy storage modules into a first network and a second network. The plant controller is arranged to control the first network to operate the BESS in a self-supply mode when the bus coupler is in an open state. The plant controller is arranged to control the second network to operate the BESS in a black-start mode when the bus coupler is in the open state.

Another aspect of the disclosure may include each of the plurality of BESS modules being composed of a plurality of electrochemical batteries, a power converter, and a transformer.

Another aspect of the disclosure may include the plant controller being operative to control a plurality of setpoints for each of the plurality of energy storage modules. The setpoints may include active power (P), reactive power (Q), voltage (V), and/or frequency (f).

Another aspect of the disclosure may include the plant controller being operative to control a plurality of setpoints for each of the plurality of energy storage modules. The setpoints may include operation modes of being connected, disconnected, grid-forming (GFM) operation, and grid-following (GFL) operation. The power converters (or inverters) need to be capable of grid-forming (GFM) operation to energize bus bars and transformers, and do not require an existing grid voltage to synchronize on. Additionally, the power converters must be able to pre-charge from the DC-side subsequent to a power outage as there is no AC voltage available when the first power converter starts up after the power outage.

Another aspect of the disclosure may include the plant controller being able to monitor present states of the plurality of energy storage modules, including a state of charge (SoC), state of health (SoH), power, voltage, temperature, and/or cell balancing.

Also, in one or more implementations, all control and communication systems are equipped with an uninterruptible power supply (UPS), so that the control system remains operational during a grid outage. Since UPS capacities are limited and the power plant can be required to stay online for several days before a black-start event occurs, the BESS should transition quickly into self-supply mode as soon as an outage is detected. In this mode, the BESS itself provides the auxiliary power for the power plant until a black-start command is received from the plant controller or system operator.

The self-supply mode operates to provide a stable voltage to the auxiliary transformer with only a portion, e.g., a minimum section of the power plant in operation. Therefore, the plant controller is configured to swap the connected rechargeable BESS enclosures over time to maintain SoC balance within the power plant.

When the electric grid is ready for black-start and the system operator sends a black-start command to the BESS, several actions may need to happen based on the power plant configuration. For example, in some embodiments circuit breakers are arranged so that the rechargeable BESS enclosures are connected to the correct network and are ready to operate. Compared to self-supply operation, it might also be required to ramp up the voltage slowly to reduce inrush currents of transformers (i.e., a “soft start” capability).

The BESS controller may be organized in different control layers, which include an array control layer and a BESS control layer. While the array control layer may manage all actions on a power plant level, the BESS control layers may deal with the control of individual BESSs including the control of individual rechargeable BESS enclosures within each of the BESSs. Typical signals that are being sent from the array control layer to the BESS control layers, are setpoints, which may include but are not limited to active power (P), reactive power (Q), voltage (V), and/or frequency (f), and BESS operation modes. The BESS operation modes may include, e.g., Disconnected, Grid-Gorming (GFM) operation, and/or Grid-Following (GFL) operation. Similarly, each of the BESS control layers may report back to the array control layer its current state, e.g. State-of-Charge (SoC), power measurements, etc.

The array control layer may be configured to manage plant-level operation by issuing setpoints and mode commands, a plurality of BESS control layers, each associated with a BESS may be configured to execute inverter and battery-level control functions.

The BESS controller may be configured to operate in a plurality of modes including: a self-supply mode, wherein at least one battery subsystem is selectively operated in grid-forming mode to energize auxiliary plant loads, a black start mode. The BESSs may be commanded to energize a disconnected grid section through a controlled voltage ramp, and a hybrid mode. A first subset of BESSs may provide self-supply while a second subset of BESSs may performs black start operations.

The BESS controller may further include a state-of-charge (SoC) balancing algorithm configured to swap active BESSs supplying the auxiliary power system with inactive BESSs to maintain balanced SoC during extended outages.

The standardized interface layer enables integration of the BESS controller layer with different busbar configurations including single busbar, bus coupler, and double busbar arrangements.

The black start mode further comprises controlling a synchronized voltage ramp to limit transformer inrush current during energization.

The hybrid mode further comprises transitioning the auxiliary subsystem from self-supply to black start operation by automatically reclosing a bus coupler breaker when nominal grid voltage is restored.

According to one aspect of the disclosure, the SoC balancing algorithm may be configured to sequentially rotate into and out of self-supply mode based on predetermined SoC thresholds.

The BESS controller may be validated using a controller-hardware-in-the-loop (C-HIL) simulation to verify transitions between self-supply, hybrid, and black start operation modes.

The above summary is not intended to represent every possible embodiment or every aspect of the present disclosure. Rather, the foregoing summary is intended to exemplify some of the novel aspects and features disclosed herein. The above features and advantages, and other features and advantages of the present disclosure, will be readily apparent from the following detailed description of representative embodiments and modes for carrying out the present disclosure when taken in connection with the accompanying drawings and the claims.

### BRIEF DESCRIPTION OF THE DRAWINGS

One or more embodiments will now be described, by way of example, with reference to the accompanying drawings, in which:

FIG. 1 schematically illustrates an embodiment of a battery energy storage system (BESS) plant including a BESS having a plurality of BESS enclosures in operative in communication with and operably connected to an energy system, e.g., an electric grid, in accordance with the disclosure.

FIG. 2 schematically illustrates an embodiment of a power plant arranged in a single bus bar configuration, in accordance with the disclosure.

FIG. 3 schematically illustrates an embodiment of a power plant arranged in a bus coupler configuration, in accordance with the disclosure.

FIG. 4 schematically illustrates an embodiment of a power plant arranged in a double bus bar configuration, in accordance with the disclosure.

FIG. 5 schematically illustrates an embodiment of a plant controller for a BESS that is composed of a controls structure and an interface to a remote terminal, in accordance with the disclosure.

The appended drawings are not necessarily to scale, and may present a somewhat simplified representation of various preferred features of the present disclosure as disclosed herein, including, for example, specific dimensions, orientations, locations, and shapes. Details associated with such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description to provide a thorough understanding of the embodiments disclosed herein, some embodiments can be practiced without some of these details. Moreover, for the purpose of clarity, certain technical material that is understood in the related art has not been described in detail to avoid unnecessarily obscuring the disclosure.

Furthermore, the drawings are in simplified form and are not to precise scale. For purposes of convenience and clarity only, directional terms such as top, bottom, left, right, up, over, above, below, beneath, rear, and front, may be used with respect to the drawings. These and similar directional terms are not to be construed to limit the scope of the disclosure. Furthermore, the disclosure, as illustrated and described herein, may be practiced in the absence of an element that is not specifically disclosed herein.

The following detailed description is merely exemplary in nature and is not intended to limit the application and uses. Furthermore, there is no intention to be bound by any expressed or implied theory presented herein. It should be understood that throughout the drawings and specification, corresponding reference numerals indicate like or corresponding parts and features.

As used herein, the term “system” may refer to one of or a combination of mechanical and electrical actuators, sensors, controllers, application-specific integrated circuits (ASIC), combinatorial logic circuits, software, firmware, and/or other components that are arranged to provide the described functionality.

The use of ordinals such as first, second, and third does not necessarily imply a ranked sense of order, but rather may only distinguish between multiple instances of an act or structure.

All numerical values of parameters (e.g., of quantities or conditions) in this specification, including the appended claims, are to be understood as being modified in all instances by the term “about” whether “about” actually appears before the numerical value. “About” indicates that the stated numerical value allows some slight imprecision (with some approach to exactness in the value; about or reasonably close to the value; nearly). If the imprecision provided by “about” is not otherwise understood in the art with this ordinary meaning, then “about” as used herein indicates at least variations that may arise from ordinary methods of measuring and using such parameters. In addition, disclosure of ranges includes disclosure of all values and further divided ranges within the entire range. Each value within a range and the endpoints of a range are hereby all disclosed as separate embodiments.

The term “controller” and related terms such as microcontroller, control, control unit, processor, etc. refer to one or various combinations of Application Specific Integrated Circuit(s) (ASIC), Field-Programmable Gate Array(s) (FPGA), electronic circuit(s), central processing unit(s), e.g., microprocessor(s) and associated non-transitory memory component(s) in the form of memory and storage devices (read only, programmable read only, random access, hard drive, etc.). The non-transitory memory component is capable of storing machine readable instructions in the form of one or more software or firmware programs or routines, combinational logic circuit(s), input/output circuit(s) and devices, signal conditioning, buffer circuitry and other components, which can be accessed by and executed by one or more processors to provide a described functionality. Input/output circuit(s) and devices include analog/digital converters and related devices that monitor inputs from sensors, with such inputs monitored at a preset sampling frequency or in response to a triggering event. Software, firmware, programs, instructions, control routines, code, algorithms, and similar terms mean controller-executable instruction sets including calibrations and look-up tables. Each controller executes control routine(s) to provide desired functions. Routines may be executed at regular intervals, for example every 100 microseconds during ongoing operation. Alternatively, routines may be executed in response to the occurrence of a triggering event. Communication between controllers, actuators and/or sensors may be accomplished using a direct wired point-to-point link, a networked communication bus link, a wireless link, or another communication link. Communication includes exchanging data signals, including, for example, electrical signals via a conductive medium; electromagnetic signals via air; optical signals via optical waveguides; etc. The data signals may include discrete, analog and/or digitized analog signals representing inputs from sensors, actuator commands, and communication between controllers.

The term “signal” refers to a physically discernible indicator that conveys information, and may be a suitable waveform (e.g., electrical, optical, magnetic, mechanical or electromagnetic), such as DC, AC, sinusoidal-wave, triangular-wave, square-wave, vibration, and the like, that is capable of traveling through a medium.

The terms “calibration”, “calibrated”, and related terms refer to a result or a process that correlates a desired parameter and one or multiple perceived or observed parameters for a device or a system. A calibration as described herein may be reduced to a storable parametric table, a plurality of executable equations or another suitable form that may be employed as part of a measurement or control routine.

A parameter is defined as a measurable quantity that represents a physical property of a device or other element that is discernible using one or more sensors and/or a physical model. A parameter can have a discrete value, e.g., either “1” or “0”, or can be infinitely variable in value.

Throughout the drawings, various embodiments of an energy system or that includes a battery energy storage system (BESS) plant having one or multiple BESSs, a plant controller, and a substation controller, in communication with and operably connected to an electric grid to generate, transmit, convert, distribute, store, and/or use energy from an external energy source, i.e., energy producers to an electrical grid, i.e., energy consumers and/or an auxiliary power system are described.

In one example, an electric grid may include, for example, an interconnected network for electricity delivery from energy producers to energy consumers. Energy producers may include external power sources, for example, power stations (e.g., thermal power stations, photovoltaic power stations, solar farms, wind power stations, wind farms, hydroelectric power stations, etc.), substations (e.g., for transforming voltage from higher to lower voltage levels, or from lower to higher voltage levels, or for performing other functions associated with transmitting electrical energy between producers and consumers), electrical power transmission and/or distribution (e.g., transmitting electrical energy from producers to substations, and/or delivering electrical energy from a transmission system to energy consumers), and/or other elements.

The next subsections will demonstrate self-supply and black-start procedures in more detail based on three different power plant configurations. Each of the power plant configurations include a plant controller, and a substation controller, wherein the plant controller is composed of a remote terminal and the control system.

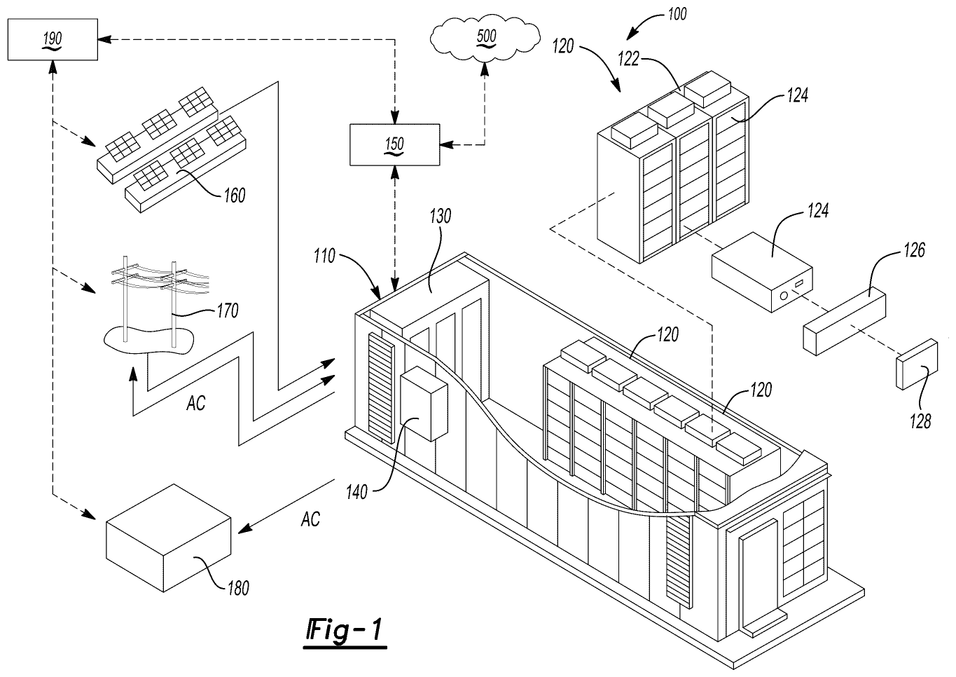

Referring to the drawings, wherein like reference numbers refer to the same or like components in the several Figures, FIG. 1 schematically illustrates a battery energy storage system (BESS) plant 100 including a BESS 110 having a plurality of nodes or BESS enclosures 120, a power conversion system 130, and a thermal management system 140.

A plant controller 150, in communication with the BESS 110, is configured to monitor and control the various components included in the BESS 110.

Each of the plurality of BESS enclosures 120 includes a battery rack 122 having a plurality of battery packs 124. Each of the plurality of battery packs 124 includes a plurality of battery modules 126 having a plurality of batteries 128 arranged within each of the plurality of battery modules 126.

The plurality of BESS enclosures 130 are coupled to one another electrically, and collectively coupled to a power conversion system 130. The plurality of BESS enclosures 130, individually and collectively, are operable to store alternating current (AC) power delivered from an external power source 160 as direct current (DC) power, for example but not limited to when the demand for power from the external power source 160 is lower that the external power source 160 is operable to generate, and/or to provide DC power for an electrical application 170, which may include an electrical grid, for example but not limited to when the demand for power is higher than the external power source 160 is operable to generate. It should be appreciated that the plurality of BESS storage enclosures 120 may be coupled to one another not only electrically, but also mechanically, and/or fluidly.

To facilitate the conversion of AC power to DC power and DC power to AC power, the power conversion system 130 is configured to standardize power input and output between the plurality of BESS enclosures 120 and the external power source 160. The power conversion system 130 may include, for example but not limited to, one or multiple power converters (or inverters) configured to convert AC power to DC power, and/or DC power to AC power.

According to one aspect of the disclosure, the BESS 110 is configured to provide power to an auxiliary power system 180, which may include but is not limited to battery and power converter thermal management, control systems, communications etc.

A substation controller 190 communicates with the plant controller 150 to operate and monitor the power plant 100 including but not limited to receiving commands from a customer and converting the commands into BESS controls and site-specific commands, as discussed above.

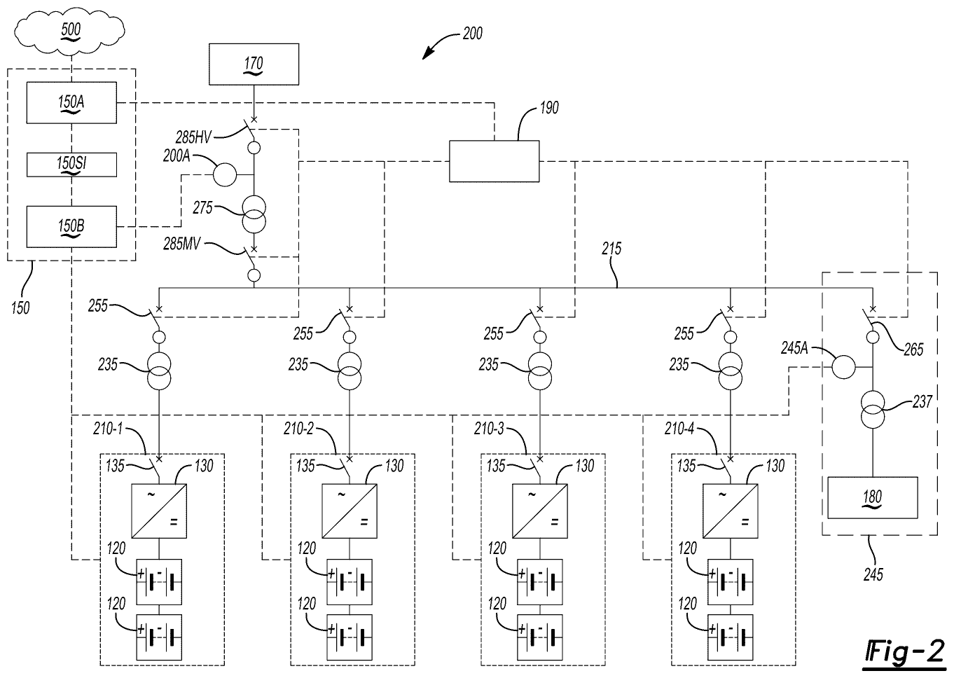

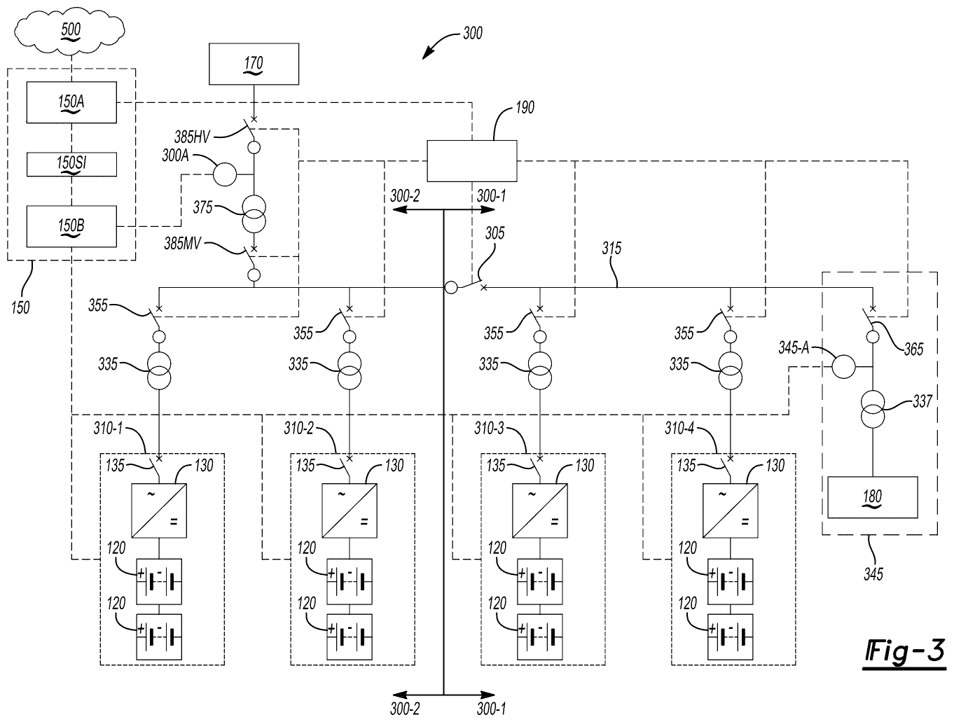

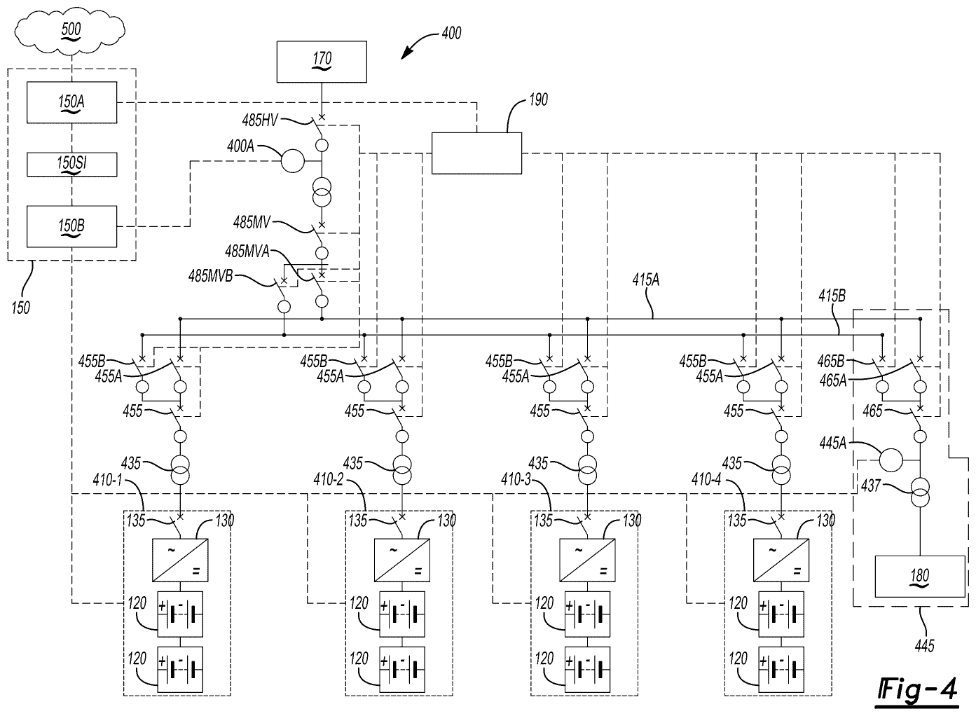

FIGS. 2, 3 and 4 schematically illustrate embodiments of a power plant 100 including as a Single Bus Bar configuration (FIG. 2), a Bus Coupler Configuration (FIG. 3), and a Double Bus Configuration (FIG. 4).

### Single Bus Bar Configuration.

As schematically illustrated in FIG. 2, according to one aspect of the disclosure, a single bus bar configuration of a battery energy storage system (BESS) plant 200 includes a plurality of battery energy storage systems (BESSs) 210-1, 210-2, 210-3, 210-4. Each of the plurality of BESSs 210-1, 210-2, 210-3, 210-4 is composed of one or multiple nodes or BESS enclosures 120 and a power converter (or inverter) 130, which are interconnected through a common bus bar 215 via BESS circuit breakers 225.

Project requirements like power and duration (e.g. full power for 1 hour or 2 hours) determine the total number of BESSs 210 as well as the number of BESS enclosures 120 connected to each power converter (or inverter) 130.

Internal disconnect circuit breakers 135 are arranged between the plurality of BESSs 210-1, 210-2, 210-3, 210-4 and transformers 235, which are arranged between the internal disconnect circuit breakers 135 and the common bus bar 215.

An auxiliary power supply circuit 245 includes an auxiliary transformer 237 connected to the common bus bar 215 via auxiliary power supply circuit breaker 265 to provide auxiliary power for auxiliary power systems 180, which may include but are not limited to battery and power converter, thermal management, and control systems, communications, etc.

With project sizes increasing and often reaching more than 100 MW, connection of the plurality of BESSs 210-1, 210-2, 210-3, 210-4 to the electric grid 170 is usually done through another step-up transformer 275, arranged between a medium voltage (MV) main circuit breaker 285MV and a high voltage (HV) main circuit breaker 285HV, at high voltage level.

A substation controller 190 operates and monitors the BESS circuit breakers 255 and the auxiliary power supply circuit breaker 265, and communicates with the plant controller 150, including the plant controller 150 composed of the remote terminal unit 150A, which interfaces with the customer and the external SCADA system 500, and the BESS controller 150B, which controls operation of the BESSs including but not limited to start/stop commands, operation modes, circuit breaker operations, etc.

When a grid outage occurs, the BESS circuit breakers 255 are commanded open, and the power plant 200 transitions into a self-supply mode. For example, BESS 120-1 gets selected to supply auxiliary power from the auxiliary power supply circuit 245 through the BESS circuit breaker 255 associated with the BESS 120-1 and the auxiliary power circuit breaker 265 while the other BESSs 120-2, 120-3, 120-4 remain offline. After a certain amount of time, BESS 120-1 might be swapped with BESS 120-2 to prevent the state-of-charge (SOC) of BESS 120-1 from falling below a certain level.

When a black-start operation is commanded, the self-supplying cores need to be shut down to safely close the MV and HV main circuit breakers 285MV, 285HV and the other BESS circuit breakers. After that, the plant controller 150 sends a start command and setpoints, which may include but are not limited to active power (P), reactive power (Q), voltage (V), and/or frequency (f), to all the power converters (or inverters) 180 to black-start the connected network with a synchronized voltage ramp.

In this configuration, the whole black-start process needs to happen within a few minutes and with a fast voltage ramp since the auxiliary power supply circuit 245 relies only on the UPS systems after the self-supply operation has been stopped.

### Bus Coupler Configuration.

To overcome the above limitations of the single bus configuration discussed above with reference to FIG. 2, a bus coupler (BC) circuit breaker 305 can be introduced into a power plant 300 as schematically illustrated in FIG. 3. In the bus coupler configuration, the Power plant 300 can be split into two separate networks, which includes a first network 300-1 and a second network 300-2. The first network 301-1 includes BESS 120-3 and BESS 120-4, which are arranged to feed the auxiliary power supply circuit (self-supply) 245, and the second network 301-2 includes BESS 120-1 and BESS 120-2, which are arranged to provide a black-start operation that is fully independent and without internal limitations on time or voltage ramp.

As soon as BESS 120-1 and BESS 120-2 have executed black-start operation, a certain section of the electric grid 170, the voltage is stable and has reached its nominal value, the self-supplying cores discussed above can be shut down. Now, the UPS systems are taking over for a short amount of time until MV main circuit breaker 385MV gets closed, which also enables BESS 120-3 and BESS 120-4 to further participate in the black-start process. Alternatively, the black-start event and the self-supplying network can be synchronized so that MV main circuit breaker 385MV can be closed seamlessly during operation.

### Double Bus Bar Configuration.

While the bus coupler configuration discussed above with reference to FIG. 3 restricts the number of BESSs being connected to a specific network, e.g. only BESS 120-3 and BESS 120-4 can be used for self-supply, a double bus bar configuration, as shown in FIG. 4, includes bus bar A 415A and bus bar B 415B, which provides full flexibility. For example, bus bar A 415A could be used as an auxiliary power supply circuit (self-supply) 445 by opening main circuit breaker A 485MVA, opening auxiliary circuit breaker B 465B and closing auxiliary circuit breaker A 465A. Each BESS 120-1, 120-2, 120-3, 120-4 can then be selected for self-supply by closing their respective BESS circuit breaker A 455A and opening its respective BESS circuit breaker B 455B. At the same time, bus bar B 415B can be used for black-start operation by closing the main breakers A, B 485MVA, 485MVB and connecting all remaining BESSs to bus bar B 415B.

The transition from this hybrid operating mode to normal operation can happen similar to the bus coupler configuration discussed above with reference to FIG. 3. As soon as the voltage on bus bar B 415B is stable and around nominal value, the BESSs connected to bus bar A 415A can shut down followed by opening all respective BESS circuit breakers A 455A and closing all respective BESS circuit breakers B 455B. With that, all BESSs as well as the auxiliary power supply circuit 445 are finally connected back to the restored electric grid 170.

One advantage of the double bus configuration illustrated in FIG. 4 compared to bus coupler configuration illustrated in FIG. 3, especially in long self-supply periods, is the possibility to maintain SoC balance within the full power plant 400 by swapping all BESSs 120-1, 120-2, 120-3, 120-4 regularly.

### Power Plant Controls for Black-Start Operations.

Referring back to FIGS. 2-4, the plant controller 150 consists of two components: a remote terminal 150A and a BESS controller 150B. Remote terminal 150A is the interface to the customer and an external Supervisory Control and Data Acquisition (SCADA) system 500.

The SCADA system 500 is a computer-based system that monitors and controls industrial processes and equipment. The SCADA system 500 uses a combination of hardware and software to collect data from devices and equipment, and then apply operational controls over long distances. SCADA system 500 may be used to monitor processes, maintain and improve efficiencies, improve quality and profitability, reduce waste, and identify problems and emergencies.

Internally, SCADA system 500 communicates with the BESS controller 150B and the substation controller 190 by which it operates and monitors the circuit breakers of the power plant 100. The SCADA system 500 receives operating commands from the customer and converts them into plant controller-specific and site-specific commands (e.g. start/stop commands, operation modes, breaker operations . . . ). Additionally, it collects operating values of the power plant 200, 300, 400 from the BESS controller 150B and the substation controller 190 and reports them to the customer and the external SCADA system 500.

While remote terminal 150A is very project-specific by nature, the BESS controller 150B can handle a variety of applications (e.g. frequency control in different markets) and configurations such as different project sizes, power converters and batteries. The BESS controller 150B processes commands from the remote terminal 150A, determines the action for each power converter (or inverter) 130 and BESS enclosure 120, and controls the power plant's operation at the point of interconnection (POI) 200A, 300A, 400A and the auxiliary power circuit's operation at the auxiliary point of connection (POI) 245A, 345A, 445A.

While these characteristics are sufficient for most of the projects and applications to date, the self-supply and black-start requirements add another level of complexity to the plant controller 150. For example, site-related information such as single or double bus bar configurations, breaker states, etc. are available in remote terminal 150A but they are also required within BESS controller 150B to connect or disconnect the appropriate BESSs. In FIG. 2 for example, the BESS controller 150B has to know that only BESS 210-3 and BESS 210-4 are available for self-supply, if the MV main circuit breaker 285MV is open.

To cope with these challenges, a new interface has been introduced between remote terminal 150A and the BESS controller 150B. The aim is to provide the required site-specific information in a generic and condensed way so that one productized the control system implementation can handle all variants of black-start operations and configurations.

Unlike conventional project specific black start solutions, the disclosed plant controller 150 architecture introduces a standardized interface between the plant remote terminal 150A and the BESS controller 150B, enabling seamless integration of site-specific breaker configurations, busbar topologies, and operational data into a common software framework. The system supports multiple operational modes including self-supply, black start, and hybrid operation, with automated state-of-charge (SoC) balancing through core-swapping algorithms to ensure extended auxiliary power supply during outages. The approach allows scalable, and reliable deployment of BESS black start applications across different grid configurations (single busbar, bus coupler, and double busbar), validated through controller-hardware-in-the-loop testing.

### Control System Structure and Remote Terminal Interface.

The plant controller 150 includes a remote terminal 150A, configured to receive external operating commands and plant configuration data, including breaker states, busbar topology, and subsystem availability, a BESS controller 150B, operatively coupled to the remote terminal 150A, and a standardized interface 150SI between the remote unit 150A and the BESS controller 150B, the standardized interface layer 150SI translating site-specific configuration data into generic control signals usable by the BESS controller 150B.

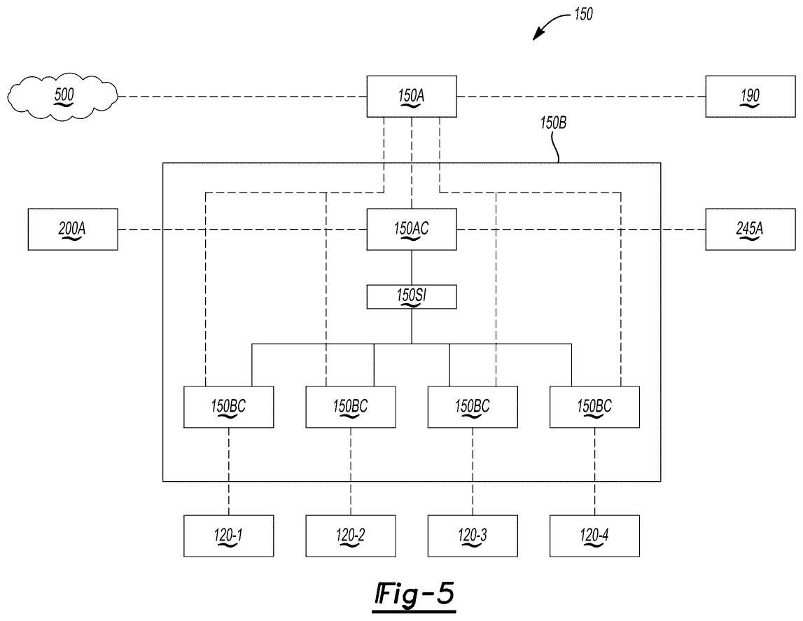

The BESS controller 150B is organized in different control layers, two of which an array control layer 150AC and a BESS control layer 150BC are shown in FIG. 5. While the array control layer 150AC manages all actions on a power plant level, the BESS control layers 150BC deal with the control of individual BESSs 110 including the control of individual rechargeable battery energy storage system (BESS) enclosures 120 within each of the BESSs 110. Typical signals that are being sent from the array control layer 150AC to the BESS control layers 150BC, are setpoints, which may include but are not limited to active power (P), reactive power (Q), voltage (V), and/or frequency (f), and BESS operation modes. The BESS operation modes may include, e.g., Disconnected, Grid-Gorming (GFM) operation, and/or Grid-Following (GFL) operation. Similarly, each of the BESS control layers 150BC reports back to the array control layer 150AC its current state, e.g. State-of-Charge (SoC), power measurements, etc.

The array control layer 150AC is configured to manage plant-level operation by issuing setpoints and mode commands, a plurality of BESS control layers 150BC, each associated with a BESS 110 and configured to execute inverter and battery-level control functions.

The BESS controller 150B is configured to operate in a plurality of modes including: a self-supply mode, wherein at least one battery subsystem is selectively operated in grid-forming mode to energize auxiliary plant loads, a black start mode, wherein the BESSs 110 are commanded to energize a disconnected grid section through a controlled voltage ramp, and a hybrid mode.

According to one aspect of the disclosure, a first subset of BESSs 110 provides self-supply while a second subset of BESSs 110 performs black start operations.

The BESS controller 150B further includes a state-of-charge (SoC) balancing algorithm configured to swap active BESSs 110 supplying the auxiliary power system 180 with inactive BESSs 110 to maintain balanced SoC during extended outages.

The standardized interface layer 150SI enables integration of the BESS controller layer 150BC with different busbar configurations including single busbar, bus coupler, and double busbar arrangements discussed herein.

The black start mode further comprises controlling a synchronized voltage ramp to limit transformer inrush current during energization.

The hybrid mode further comprises transitioning the auxiliary subsystem from self-supply to black start operation by automatically reclosing a bus coupler breaker when nominal grid voltage is restored.

According to one aspect of the disclosure, the SoC balancing algorithm is configured to sequentially rotate BESSs 110 into and out of self-supply mode based on predetermined SoC thresholds.

The BESS controller 150B is validated using a controller-hardware-in-the-loop (C-HIL) simulation to verify transitions between self-supply, hybrid, and black start operation modes.

The remote terminal 150A can interact with both the array control layer 150AC and the BESS control layers 150BC. While the latter is employed to report power plant configurations and connection states of the BESSs the main control interface between the remote terminal 150A and the array control layer 150AC is the Plant Operation Mode (e.g. GFL, GFM, Self-Start (SS), Black-Start (BS), BS/SS).

If, for example, the remote terminal 150A sends a GFM operation mode command to the array, i.e., all of the BESSs, the full power plant 200, 300, 400 and therefore all BESSs included therein are supposed to go into GFM operation mode, and the array control layer 150AC sends the respective commands and setpoints, which may include but are not limited to active power (P), reactive power (Q), voltage (V), and/or frequency (f), to each of the BESSs.

If the remote terminal 150A, however, commands the array, i.e., all of the BESSs, to go into SS, the array control layer 150AC sends a GFM operation mode only to the BESSs associated with self-supply, in FIG. 2, for example only BESS 210-3 and BESS 210-1. The same principle applies to the other operation modes like BS and BS/SS.

Commanded application modes may include an Offline mode, a Standby mode, a Grid Following mode, a Grid Forming mode that includes Droop, Isochronous, and Inertia modes, a Self-Supply mode, and a Black-start mode that may include self-supply.

In the Offline mode, power plant 100, 200, 300, 400 and its components will be brought into Disconnected Operation Mode.

In the Standby mode, the power plant and its components will be brought into Standby Operation Mode. The BESSs will need to be connected to the Main Grid.

In the Grid-Following mode, the power plant and its components will be brought into the Grid-Following Operation Mode with the option to perform steady-state secondary control. The BESSs will need to be connected to the Main Grid.

In the Grid-Forming modes, the voltage and frequency reference points are propagated from the Array module down to each BESS and BESS enclosure. In every application, though, the control strategy on the power plant level (Array) is different and in combination with the different electrical network configurations on each BESS, there is a need to introduce a new way of defining how the Array module needs to operate.

In the Grid-Forming Droop P/Q mode, the power plant and its components will be brought into the Grid-Forming Droop Operation Mode and the steady-state secondary control on the power plant level (Array) will be set to active and reactive power control. The BESSs will need to be connected to the Main Grid.

In the Grid-Forming Droop mode, the power plant and its components will be brought into the Grid-Forming Droop Operation Mode and the steady-state secondary control on the power plant level will be disabled. The BESSs will need to be connected to the Main Grid.

In the Grid-Forming Isochronous mode, the power plant and its components will be brought into the Grid-Forming Droop Operation Mode and the steady-state secondary control on the power plant level will be set to frequency and voltage control. The BESSs will need to be connected to the Main Grid.

In the Grid-Forming Inertia mode, the power plant and its components will be brought into the Grid-Forming Inertia Operation Mode and the steady-state secondary control on the power plant level will be set to active and reactive power control. The BESSs will need to be connected to the Main Grid.

In the Self-Supply mode, the part of power plant and its components connected to the auxiliary power supply circuit will be brought into the Grid-Forming Droop Operation Mode and will supply the auxiliary power to preserve the operation of the Power plant.

In the Black-Start with Self-Supply mode, the components connected to either auxiliary power supply circuit or the Main Grid will be brought into the Grid-Forming Droop Operation Mode and the auxiliary power supply circuit will provide the needed power for the power plant self-consumption while the main network will be used to black-start the connected electric grid by ramping up the electric grid's voltage.

In the Black-Start mode, the part of power plant and its components that are connected to the Main Grid will be brought into the Grid-Forming Droop Operation Mode and will attempt to ramp up the voltage of the network/sub-network to a configurable voltage level.

The plant controller for battery energy storage systems (BESS) provide self-supply and black start capability. Unlike conventional project specific black start solutions, the disclosed control architecture introduces a standardized interface between a remote terminal unit (RTU) and a generic BESS (system) controller, enabling seamless integration of site-specific breaker configurations, busbar topologies, and operational data into a common software framework. The system supports multiple operational modes including self-supply, black start, and hybrid operation, with automated state-of-charge (SoC) balancing through core-swapping algorithms to ensure extended auxiliary power supply during outages. The approach allows scalable, and reliable deployment of BESS black start applications across different grid configurations (single busbar, bus coupler, and double busbar), validated through controller-hardware-in-the-loop testing.

Operation of each BESS via the plant controller in the various application modes may include all or a portion of the BESS being connected to the electric grid to transfer electric power therebetween in the grid-following (GFL) mode, or one of the grid-forming (GFM) modes.

Operation of the BESS via the plant controller in the various application modes may include all or a portion of the BESS being connected to an internal or auxiliary power grid to transfer electric power in the self-supply mode and/or the black-start mode.

Operation of the BESS via the plant controller in the various application modes may include and all or a portion of the BESS being disconnected from the main grid and the auxiliary grid, and/or being in the standby mode.

A BESS, in terms of electrical components, is connected over a circuit breaker to a main electrical circuit/grid which is part of the electric grid. However, in Grid-Forming applications we can have more than one electrical circuit to which a BESS can be connected (like auxiliary, critical loads, etc.). Both the BESS control layers and the array control layer of the control system will need to monitor the state of a BESS's electrical connection, as it is essential for the operation of a Power Capacity Manager (PCM). This creates the need for a definition of a list of possible electrical networks that a core can implement, and which will define the way it is going to be operated.

The electrical networks include a main grid network, an auxiliary grid network, and a disconnected network, with each of the BESSs being assigned to one of the electrical networks. The plant controller and substation controller assign permission states to the BESSs based upon whether the respective core is assigned to the main grid network, the auxiliary grid network, or the disconnected network. The assigned permission state determines the actual operation mode of the core and its nodes, with the circuit breakers being controlled based thereon.

Embodiments in accordance with the present disclosure may be embodied as an apparatus, method, or computer program product. Accordingly, the present disclosure may take the form of an entirely hardware embodiment, an entirely software embodiment (including firmware, resident software, micro-code, etc.), or an embodiment combining software and hardware aspects that may generally be referred to herein as a “module” or “system.” Furthermore, the present disclosure may take the form of a computer program product embodied in a tangible medium of expression having computer-usable program code embodied in the medium.

Any combination of one or more computer-usable or computer-readable media may be utilized. For example, a computer-readable medium may include one or more of a portable computer diskette, a hard disk, a random access memory (RAM) device, a read-only memory (ROM) device, an erasable programmable read-only memory (EPROM or Flash memory) device, a portable compact disc read-only memory (CDROM), an optical storage device, and a magnetic storage device. Computer program code for carrying out operations of the present disclosure may be written in a combination of one or more programming languages.

Elements of the plant controller described herein may be implemented in a cloud computing environment. In this description and the following claims, “cloud computing” may be defined as a model for enabling ubiquitous, convenient, on-demand network access to a shared pool of configurable computing resources (e.g., networks, servers, storage, applications, and services) that can be rapidly provisioned via virtualization and released with minimal management effort or service provider interaction, and then scaled accordingly. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

For validation of the interface between the remote terminal 150A and the BESS controller 150B a Controller-HIL (Hardware-in-Loop) methodology is used.

### Hardware-in-Loop (HIL) Verification—Model Overview.

A hardware-in-the-loop (HIL) model has been used to validate the battery energy storage system (BESS) plant controls, which replicates the bus coupler configuration of FIG. 2 with an additional power converter/battery connected to BESS 210-1. The nominal voltage levels are 110 kV on the HV side, 33 kV on the MV side and 690 V on the power converter terminals. Each power converter has an apparent power of 4 MVA, with the total rating of the BESS being 20 MVA. The current status of the power plant 200 can be obtained from different text boxes within the model, e.g. P, Q, V and f values, breaker states, SoC values etc.

### Self-Supply (SS) State-of-Charge (SoC) Balancing.

While power plant 200 is operating in the Self-Supply mode, the BESS controller 150B can be parametrized to utilize a swapping algorithm and help balance the SoC within the power plant 200.

BESS 210-3 and BESS 210-4 are being swapped to balance their SoC level, as these two are the only ones connected to the auxiliary power supply circuit 145. power plant 200 is parametrized to only utilize 5% of SoC of each BESS 210-3, 210-4 before switching to the next one.

### Hybrid Power Plant Operation Mode (Bus Coupler).

While the power plant 300 is operating in the Hybrid Power Plant Operation Mode, BESS 310-3 and BESS 310-4 are being arranged to maintain the voltage level of the auxiliary power supply circuit 345, while BESSs 310-1 and BESS 310-2 are being utilized to perform a voltage ramp and execute a black-start operation on the connected sub-network of the electric grid 170.

The technical paper titled ‘Grid-Forming Plant Controls for Self-Supply and Black Start Applications of Battery Energy Storage Systems,’ by Ioannis Arvanitis, Stefan Henniger, presented at the 23^{rd} Wind & Solar Integration Workshop in Helsinki, Finland (October 2024), is hereby incorporated by reference in its entirety to provide further information about the HIL Verification method used.

Each BESS is selectively electrically connectable to one bus bar, as illustrated in FIG. 2 and FIG. 3, or multiple bus bars, as illustrated in FIG. 4, via core circuit breakers to supply electric power to an electric grid via the respective core circuit breakers, by action of the plant controller, as detailed with reference to the embodiments illustrated herein.

Each BESS advantageously includes one or an array of rechargeable BESS enclosures, and a power converter (or inverter). Each BESS may also include one or multiple sensors, a thermal management system, and one or multiple internal disconnect circuit breakers.

The plant controller may be composed of a remote terminal unit and a control system. The plant controller, in communication with the substation controller, is arranged to monitor and control different elements of the BESSs including the BESS enclosures, and their respective BESS circuit breakers. This includes electrically connecting the plurality of BESSs to the electric grid via the respective BESS circuit breaker and one bus bar (FIG. 2 and FIG. 3) or multiple bus bars (FIG. 4) to transfer electric power, wherein the transfer of electric power may be related to a charging mode or a discharging mode.

The rechargeable battery energy storage system (BESS) enclosures include, by way of a non-limiting example, rechargeable electrochemical devices. Each of the plurality of BESS enclosures is a DC power source that is couplable to an external power source, an electric grid, or a power generator to effect charging, wherein the external power source may originate from solar, wind, geothermal, nuclear, natural gas, coal, diesel fuel, methane, biofuel, or another energy source.

Each rechargeable BESS enclosure is a DC energy storage device (or battery) having one or more rechargeable electrochemical cells. The batteries may include one or more of various types of batteries, such as lithium-ion batteries, lithium iron phosphate batteries, silver-oxide batteries, nickel-zinc batteries, nickel metal hydride batteries, lead-acid batteries, nickel-cadmium batteries, lithium nickel manganese cobalt oxides (NMC) batteries, lithium nickel cobalt aluminum oxides (NCA) batteries, lithium ion manganese oxide (LMO) batteries, lithium cobalt oxide batteries, fuel cells, or other types of batteries. Alternatively, or in addition, the DC energy storage devices may be in the form of ultracapacitors, flywheels, fuel cells, etc., without limitation.

The rechargeable BESS enclosures may have control components associated therewith. The control components may be, for example, configured to individually manage the charge and discharge of each of the batteries. The control components may include, for example, battery management systems (BMS). In some examples, each of the batteries may have a dedicated on-board control component (e.g., a battery management system). The control component for each of the batteries may be implemented by a computing device, and/or may communicate with a central management component. Additionally, or alternatively, the central management component may manage the charge and discharge of the batteries collectively. The charge and discharge of the batteries may be controlled using devices and control algorithms, such as circuits with circuit breaker controls, charge or discharge controllers, charge or discharge regulators, battery regulators, and/or the like, so that each of the batteries may be controlled to be in a state of receiving electricity from a source at a particular rate, in a state of outputting electricity to a load at a particular rate, or in a state of being idle.

In some examples, the power converter may include a structure or component that may be applicable to the batteries collectively. In some examples, the power converter may include multiple structures or components, each of which may be respectively applicable to a corresponding battery of the batteries. In some examples, the power converter may include a structure or component that may be applicable to some of the batteries collectively, and the power converter may include multiple structures or components, each of which may be respectively applicable to a corresponding battery of other batteries of the batteries. In some examples, a power conversion system (PCS) may be used for multiple BESS modules collectively (e.g., for converting electrical energy from the multiple BESS modules into a desired form for outputting to a load, or for converting electrical energy from a source into a desired form for inputting to or charging the multiple BESS modules).

The thermal management system may include any type of device configured to remove heat from the BESS module and/or add heat to the BESS module. The thermal management system may use air, liquid, solid material, gaseous material, and/or another type of suitable medium or material to remove heat. In some examples, the thermal management system may include heat sinks and/or thermal management fins. In some examples, the thermal management system may include fans (e.g., for moving air in air-cooling), pumps (e.g., for moving a liquid in liquid-cooling), compressors (e.g., for vapor-compression refrigeration), or another type of device for thermal management. The thermal management system may have any desired configuration (e.g., shape, size, weight, functionality, etc.), and/or may be placed, oriented, or distributed in association with sensor(s), and the power converter.

In some examples, the computing device may control the components based on instructions from another computing device (e.g., the energy storage controller device). Additionally, or alternatively, data associated with the BESS module may be recorded or stored, including, for example, data measured by the sensor(s), data used by the BESS module (e.g., parameters for controlling the batteries, parameters for controlling the power converter, or parameters for controlling the thermal management system), or other type(s) of data. The recorded or stored data may be used or processed by the computing device and/or another computing device (e.g., the energy storage controller device) in connection with one or more aspects described herein.

The plant controller is arranged to communicate with and control operation of each of the BESSs, employing the remote terminal unit and the control system. The plant controller is a collection of control processes that are used to control the power plant including a BESS. A Market Dispatch Unit (MDU) is responsible for generating active and reactive power dispatch set-points to fulfill the requirements of one or multiple market applications. These set-points are being communicated to the array control layer of the control system which, in turn, distributes the dispatch to the BESS control layers, which then distribute them to BESS enclosures.

The various elements of the BESS are arranged to communicate with each other via a network, including employing interconnected wired and/or wireless communication links.

The sensors may be any type of sensor capable of measuring or assessing one or more parameters of the BESS. The sensors may include, for example, voltage sensors, current sensors, frequency sensors (e.g., power bus frequency sensors), power sensors (e.g., for measuring the active power or reactive power of an electric grid), or other types of sensors for obtaining measurements associated with the system. The sensors may have any desired configuration (e.g., shape, size, weight, functionality, etc.). The sensors may be configured to obtain measurements of an electric grid, including the power bus. For example, the sensor may be configured to measure the frequency of alternating current as transmitted via the power bus (e.g., the voltage at the bus bar associated with or included in the power bus), or the sensor may be configured to measure the frequency of alternating current as transmitted via the power bus, e.g., the voltage at the bus bar associated with or included in the power bus. The sensors may be coupled to the electric grid in any desired manner, e.g., by electrically coupling to the points of connection of the electric grid. The sensors may send measured data to the energy storage controller device. It is contemplated that the system may employ one or multiple sensors (not shown).

The BESS may refer to any system configured to store energy that is convertible to electric power. The BESS may include the rechargeable BESS enclosures being arranged as a centralized system or as a distributed system. BESS 110 may include one or more BESS modules. In some examples, the BESS modules may be located in a single physical location, such as a site. In some examples, the BESS modules may be distributed in multiple physical locations. It is contemplated that the BESS modules may include one or multiple cores, each having one or multiple nodes or BESS enclosures.

Black-start operation is a process of restoring, after a power outage or shutdown, an electric power station, i.e., a BESS, to operation without relying upon an external power source.

### Power Plant Configurations and Black-Start Concepts.

To provide black-start functionality, a BESS needs to fulfill several requirements. The power converter(s) (or inverter) needs to be capable of grid-forming (GFM) operation, so that they can energize bus bars and transformers without requiring an existing grid voltage to synchronize on. Additionally, they must be able to pre-charge from the DC-side subsequent to a power outage as there is no AC voltage available when the first power converter starts up after the power outage.

Also, all control and communication systems must be equipped with an uninterruptible power supply (UPS), so that the control system remains operational after a grid outage. Since UPS capacities are limited and the power plant can be required to stay online for several days before a black-start event happens, the BESS needs to transition into a self-supply mode as soon as an outage is detected. In this mode, the BESS itself provides auxiliary power for the power plant during the grid outage, until a black-start command is received from the system operator.

An objective in self-supply mode is to provide a stable voltage to the auxiliary transformer with only a portion, e.g., a minimum section of the power plant, in operation. Therefore, the plant controller will have to swap the connected batteries over time to maintain State-of-Charge (SoC) balance within the BESS.

When the electric grid is ready for black-start operation and the system operator sends a black-start command to the BESS, several actions need to happen based on the power plant configuration. For example, breakers must be arranged so that the batteries are connected to the right network and are ready to operate. Compared to self-supply operation, it might also be required to ramp up the voltage slowly to reduce inrush currents of transformers (so-called soft start capability).

The detailed description and the drawings or figures are supportive and descriptive of the present teachings, but the scope of the present teachings is defined solely by the claims. While some of the best modes and other embodiments for carrying out the present teachings have been described in detail, various alternative designs and embodiments exist for practicing the present teachings defined in the claims.

What is claimed is:

1. An energy storage system including a battery energy storage system (BESS), the energy system comprising:
a plant controller in communication with and operatively connected to a plurality of battery energy storage systems (BESSs);
wherein each of the plurality of BESSs is composed of a plurality of BESS enclosures, a bus bar, a bus coupler, and a plurality of BESS circuit breakers;
wherein each of the plurality of BESSs is connectable via a respective one of the plurality of BESS circuit breakers to the bus bar to supply electric power to an electric grid;
wherein the bus bar includes the bus coupler;
wherein the plant controller is arranged to control the bus coupler to separate the plurality of BESSs into a first network and a second network;
wherein the plant controller is arranged to control the first network to operate the power plant in a self-supply mode when the bus coupler is in an open state; and
wherein the plant controller is arranged to control the second network to operate the power plant in black-start mode when the bus coupler is in the open state.

2. The system of claim 1, wherein each of the plurality of BESSs comprises a BESS that is composed of a plurality of BESS enclosures, a power converter, and a transformer.

3. The system of claim 2, further comprising the power converter being operative to perform grid-forming (GFM) operation to energize bus bars and transformers.

4. The system of claim 2, further comprising the power converter being operative to pre-charge from a DC-side subsequent to a power outage.

5. The system of claim 1, further comprising the plant controller being operative to control a plurality of setpoints for each of the plurality of BESSs, wherein the setpoints include active power (P), reactive power (Q), voltage (V), and/or frequency (f).

6. The system of claim 1, further comprising the plant controller being operative to control a plurality of setpoints for each of the plurality of BESSs, wherein the setpoints include operation modes of being connected, disconnected, grid-forming (GFM) operation, and grid-following (GFL) operation.

7. The system of claim 1, further comprising the plant controller being operative to monitor a present state of the plurality of BESSs including a state of charge (SoC).

8. The system of claim 1, further including an auxiliary power supply circuit including an auxiliary power system, an auxiliary transformer, and an auxiliary circuit breaker;
wherein the plant controller is in communication with and operatively connected to the auxiliary power circuit; and
wherein the auxiliary power supply is connectable via the auxiliary circuit breaker to the bus bar.

9. A method of controlling an operation mode of an energy system including a battery energy storage system (BESS), the method comprising:
providing a plant controller in communication with and operably connected to a plurality of battery energy storage systems (BESSs);
wherein each of the plurality of BESSs is composed of a plurality of BESS enclosures, a bus bar, a bus coupler, and a plurality of BESS circuit breakers;
wherein each of the plurality of BESSs is connectable via a respective one of the plurality of BESS circuit breakers to the bus bar to supply electric power to an electric grid;
wherein the bus bar includes the bus coupler;
controlling, via the plant controller, the bus coupler to separate the plurality of BESSs into a first network and a second network;
arranging the plant controller to control the first network to operate the power plant in a self-supply mode when the bus coupler is in an open state; and
arranging the plant controller to control the second network to operate the power plant in black-start mode when the bus coupler is in the open state.

10. The method of claim 9, wherein each of the plurality of BESSs comprises a BESS that is composed of a plurality of BESS enclosures, a power converter, and a transformer.

11. The method of claim 10, further comprising performing, via the power converter, a grid-forming (GFM) operation to energize bus bars and transformers.

12. The method of claim 10, further comprising pre-charging the power converter from a DC-side subsequent to a power outage.

13. The method of claim 9, further comprising controlling, via the plant controller, a plurality of setpoints for each of the plurality of BESSs, wherein the setpoints include active power (P), reactive power (Q), voltage (V), and/or frequency (f).

14. The method of claim 9, further comprising controlling, via the plant controller, a plurality of setpoints for each of the plurality of BESSs, wherein the setpoints include operation modes of being connected, disconnected, grid-forming (GFM) operation, and grid-following (GFL) operation.

15. The method of claim 9, further comprising monitoring, via the plant controller, a present state of the plurality of BESSs including a state of charge (SoC).

16. The method of claim 9, further comprising providing an auxiliary power supply circuit including an auxiliary power system, an auxiliary transformer, and an auxiliary circuit breaker in communication with and operatively connected to the plant controller; and
selectively connecting, via the plant controller, the auxiliary power supply via the auxiliary circuit breaker to the bus bar.

17. A power plant comprising:
a plurality of BESSs;
an electric grid;
a plant controller in communication with and operative connected to the plurality of BESSs;
an external supervisory control and data acquisition (SCADA) system, wherein the plant controller is in communication with the external SCADA system;
a substation controller in communication with the plant controller;
wherein each of the plurality of BESSs is composed of a plurality of BESS enclosures, a bus bar, a bus coupler, and a plurality of BESS circuit breakers;
wherein each of the plurality of BESSs is connectable via a respective one of the plurality of BESS circuit breakers to the bus bar to supply electric power to the electric grid;
wherein the substation controller is operatively connected to the plurality of BESS circuit breakers;
wherein the bus bar includes the bus coupler;
wherein the plant controller is arranged to control the bus coupler to separate the plurality of BESSs into a first network and a second network;
wherein the plant controller is arranged to control the first network to operate the power plant in a self-supply mode when the bus coupler is in an open state; and
wherein the plant controller is arranged to control the second network to operate the power plant in black-start mode when the bus coupler is in the open state.

18. The power plant of claim 17, further comprising the plant controller being operative to control a plurality of setpoints for each of the plurality of BESSs, wherein the setpoints include active power (P), reactive power (Q), voltage (V), and/or frequency (f).

19. The power plant of claim 17, further comprising the plant controller being operative to control a plurality of setpoints for each of the plurality of BESSs, wherein the setpoints include operation modes of being connected, disconnected, grid-forming (GFM) operation, and grid-following (GFL) operation.

20. The power plant of claim 17, further comprising the plant controller being operative to monitor a present state of the plurality of BESSs including a state of charge (SoC).
